(19) United States
(12) Patent Application Publication
(10) Pub. No.: US 2017/0236962 A1
(43) Pub. Date: Aug. 17, 2017

(54) SOLAR CELL ELEMENT AND CELL ARRANGEMENT MADE FROM THE ELEMENTS

(71) Applicant: Ecosolifer AG, Samen (CH)

(72) Inventors: Ferenc Beleznay, Budapest (HU); Agoston Nemeth, Budapest (HU)

(21) Appl. No.: 15/502,029

(22) PCT Filed: Jul. 29, 2015
(86) PCT No.: PCT/IB2015/055714

§ 371 Date: Feb. 6, 2017

(30) Foreign Application Priority Data
Aug. 7, 2014 (HU) P1400380

(51) Int. Cl. H01L 31/056; H01L 31/0749; H01L 31/046; H01L 31/0236; H01L 31/0224

(52) U.S. Cl. CPC H01L 31/056; H01L 31/02363; H01L 31/022466; H01L 31/046; H01L 31/0749

(57) ABSTRACT

Solar cell element with a carrier (14), a thin film layer structure on a surface of the carrier, the thin film layer structure comprises a transparent first electrode layer (20), active layers (22, 23) in which a portion of the energy of the incident light is absorbed and a second electrode layer (24), the thin film layer structure has a light reflecting rear boundary surface, and the surface of said carrier (14) comprises at least two planar surface regions that close and angle with and form continuation of each other so that between them a recess is formed, and a portion of light reflected from the rear boundary surface of a first surface region will pass through the recess to fall on the second surface region and generates additional charge carriers therein, and the thin film structure on the surface regions constitutes a uniform uninterrupted thin film structure, wherein the extent of absorption of the thin film structure in the visible spectral region of light is at most 90% of the energy of the incident light. A plurality of the solar cell elements forms a solar cell arrangement, in which the carrier (14) is common for all cell elements and a surface of the carrier (14) has a plurality of juxtaposed pyramid-like recesses on which the thin film layers are provided.

The invention relates to a solar cell element that comprises a carrier; a thin film layer structure provided on a surface of the carrier and mechanically supported by the carrier, and when the cell element is seen from the direction of incident light the thin film layer structure comprises a transparent and electrically conductive first electrode layer; active layers in which a portion of the energy of the incident light is absorbed and an electrically conductive second electrode layer, wherein light energy absorbed in the active layers generates positive and negative charge carriers that proceed to a corresponding one of the first and second electrodes.

Solar cells have two basic types, namely crystalline cells made predominantly by bulk silicon wafers and thin film layer cells. Crystalline cells can be manufactured with higher costs which come not only from the use of a more expensive bulk material but also from the excess cost of organizing and mounting individual cells into larger modules. In contrast to this in case of thin film layered solar cells the manufacturing cost is lower, they have less weight therefore such cells are seriously competitive with crystal type cells although they have smaller efficiency.

A known drawback of solar cells lies in reflection losses which come predominantly from the fact that light is reflected at the boundary surfaces of different materials, layers. The extent of reflection might depend on the material properties of the layers and also on the incidence angle of light, and represents the loss of a part of the solar energy, as reflected light that does not enter the thin film layers cannot be utilized there. For decreasing such losses anti-reflection layers are often used on the outer surface of solar cells that decrease reflection but increase costs.

For increasing absorption in the thin film layers there are other special measures, especially light trapping which is described e.g. in the publication L. C. Andreani, A. Bozzola and M. Liscidini (25 May 2012) “The importance of light trapping in thin-film solar cells” SPIE Newsroom. doi: 10.1117/2.1201205.004259. Such techniques aim at increasing the optical path of light in the semiconductor, which enhances the absorption efficiency for the same material thickness. A more detailed description of light trapping in the publication of Joachim Müller et. Al entitled: TCO and light trapping in silicon thin film solar cells” (Solar Energy 77 (2004) 917-30. A part of this technique is the use a reflective surface at the rear electrode layer so that the light reflected within the thin layer will also contribute to generation of charge carriers. On the other hand, light trapping has the main objective to keep the incident light within the thin film and to increase thereby its absorption, and no way to allow a part of the reflected light to leave the thin film and to let its energy not utilized.

A further reference to the formation of the rear electrode as a mirror can be found in U.S. Pat. No. 8,035,028B2, in which in column 13, lines 4 to 7 describe such a use of a mirror as light trapping but also for the sole purpose of increasing absorption of light in the thin film and not to let light escape from the thin film.

There is a further (not so serious) problem, namely all thin film structure have a predetermined spectral sensitivity which is not uniform within the whole spectral range of the incident light. If there was a possibility to broaden the spectral range of any given incident light which can be utilized for energy generation, this would mean a slight but non-negligible improvement in efficiency.

Apart from the efficiency problem of a single solar cell, a further problem lies in that in any given location the sun moves along a path, and solar panels installed in a fixed position cannot follow this path, therefore a part of the solar energy will get lost because the normal to the surface of the solar cells will close higher angles as the sun moves.

Such losses can be decreased by the special design of solar cells using certain optical properties.

In the field of optics the use of corner cubes is known, and these correspond to three plates that form a cube portion and intersect each other at a corner and they have reflecting mirror-like surface designs. The corner cube with the open cavity formed by such optical mirrors arranged in this way has a property according to which the rays of the incident light will be reflected after a triple reflection always against the direction of the incident rays. Such properties of corner cubes are widely used, perhaps the most general use is the “cat eye” mounted on bicycles or other vehicles that ensure a good visibility of objects on which they are mounted.

These favourable properties of corner cubes, i.e. the fact that they break the light arriving from any direction in the interior of the cavity, haven already been utilized for solar cells.

Publication US 2011/0083718 A1 shows in FIGS. 43 and 44 a solar cell arrangement formed by corner cube configurations of separate distinct cells, but in paragraph [0161] it is described that the property of solar cells that they reflect a part of incoming light, although it would have been required that they absorb all incident light. It is also described that this effect is decreased by the use of anti-reflection coatings but cannot reach a full suppression. The previously described objective, i.e. to increase absorption in the cell where light enters can be seen also in this publication.

The main ground of using corner cube solar cells lies in that in case of scattered incoming light or when the sun takes its path the amount of generated energy is less dependent from the actual angle of incidence of the incoming light.

Mainly because of the operation at broad angular range of incident light the use of corner cube solar cells has been suggested in different other publications, e.g. in US 2014/0014161 A1 in which FIGS. 10 to 12 such modules are arranged along a spherical sell surface.

The previously cited U.S. Pat. No. 8,035,028 also uses planar cells arranged in a special spatial configuration, and the individual cells are electrically connected to each other (in most of the cases in series).

There is a need to increase efficiency of thin film solar cells without the increase or noticeable increase of the manufacturing cost.

The primary object of the present invention is to meet this need and to increase efficiency with simple ways.

A second object of the invention is to act against the general trend of designing thin film cells by increasing the absorption in a solar cell element as much as possible, e. g. by light trapping, and to find ways how a reflected light can be utilized if the absorption in the thin film layers is smaller and not higher than usual.

A third object of the invention is to combine the advantage of the decreased sensitivity against sun movement with reaching the second object i.e. to allow smaller absorption in the thin film layers of a single solar cell element.

A fourth object is to improve the utilization of the spectral range of the incident light in spite of the predetermined properties of the thin film layer used.

A fifth objective of the invention is to provide a solar cell arrangement that uses the favourable properties of such solar cell elements that satisfy the first four objectives.

According to the invention it has been discovered that there can be no need to decrease the reflection of the thin film layer structure on the carrier to a value close to zero with excess costs but under specific circumstances it can even be increased. Such a circumstance can be if the light is not absorbed fully by the thin film layer in which it enters first at a first planar region of the cell but it is reflected therefrom to proceed to a second planar surface region of the same cell that closes and angle with the first region and when this reflected light enters in the thin film layer a part of its energy is used to generate electrical energy, and if there remains further portion of this light which has not been absorbed in the second thin film layer the non absorbed portion exits from this second surface layer and might proceed to a third planar surface region of the same cell and its energy is used again there.

A further discovery of the present invention is connected with the basic properties of thin film cells, namely that for the sake of the most perfect absorption of the incident light (which was thought as required) the central intrinsic layer of the cell has been chosen comparatively thick. The increased layer thickness increases however the resistance which should be overcome by the charge carriers, and along a longer path towards the electrodes the probability of recombination also increases, i.e. along the movement of the charge carriers losses are generated. If the thickness of the central layer is reduced by which the layer gets more transparent, then the number of the generated charge carrier pairs will certainly decrease but at the same time the resistive and recombination losses will also decrease. If the energy of the reflected portion of light is utilized again in a further region of the cell, then the missing energy will not be a lost energy, but it is utilized but not at its first entry in the cell.

The aforementioned multiple penetrations have certain structural preconditions that concern how these distinct surface regions are arranged.

If these structural conditions are met, this can be the source of further advantages connected with the increased period of generating energy during a day at a fixed location.

These objects can be reached in a solar cell element that comprises a carrier; a thin film layer structure provided on a surface of the carrier and mechanically supported thereby, and when the cell element is seen from the direction of incident light the thin film layer structure comprises a transparent and electrically conductive first electrode layer; active layers in which a portion of the energy of the incident light is absorbed and an electrically conductive second electrode layer, wherein the light energy absorbed in the active layers generates positive and negative charge carriers that proceed to a corresponding one of the first and second electrodes and according to the invention the thin film layer structure has a light reflecting rear boundary surface, and the surface of the carrier on which the thin film layer structure is provided comprises at least two substantially planar surface regions that close and angle with and form continuation of each other so that between them a recess is formed, and a portion of light reflected from said rear boundary surface of a first one of the planar surface regions will pass through the recess to fall on the second one of the planar surface regions and will penetrate in the thin film layers of the second surface region and generates there additional charge carriers, wherein the roles of the first and second surface regions can be interchanged, and the thin film structure on the surface regions constitutes a uniform uninterrupted thin film structure; and the extent of absorption of the thin film structure in the visible spectral region of light is at most 90% of the energy of the incident light.

A preferred embodiment comprises three of such planar surface regions that form a pyramid, and light reflected from any of these regions will reach a neighbouring second region and from there a third region.

In a further preferred embodiment the planar surface regions constitute a pyramid of at least four of such planar surface regions.

At a most preferred embodiment the planar surface regions are arranged to form a corner cube in which the tip falls in the deepest part of the recess. From the point of view of easy manufacture it is preferred if the depth of the corresponding recesses falls between about 1 and 3 mm.

In an embodiment the reflecting surface is formed by the reflective design of the second electrode.

The extent of absorption is decreased by the thinner design of least one of the active layers compared to those of similar thin film solar cells where reflected light is not utilized to generate electrical energy.

According to a further aspect of the present invention a solar cell arrangement is provided that comprises a plurality of the solar cell elements defined, and in the arrangement the carrier is a rigid substantially planar plate which is common for all of said solar cell elements and a surface of the carrier is structured to have a plurality of juxtaposed pyramid like recesses on which the aforementioned thin film layers are provided, and the solar cell elements are arranged so as to constitute separate modules and in each module all solar cell elements are connected in parallel with each other so that each module has two electrodes, and the modules on a carrier can be connected as required by the intended use.

The resulting voltage can be increased if the separate modules are connected in series. The series connection can be realized if in the modules the solar elements are regularly arranged so that each module has two parallel sides, and between two neighbouring modules spaces are provided, and along the spaces respective grooves are provided at different phases of the layer deposition, that realize the series connection of the modules.

In a preferred embodiment the surface of the carrier that faces towards incident light is a planar surface, and the spatial arrangement of the cell elements comprising projections and recesses is formed at the rear side of the carrier.

In an alternative embodiment the rear surface of the carrier is a planar surface and the spatial arrangement that comprises projections and recesses is formed at the front side of the carrier.

In a further alternative embodiment each module is a separate cell and the cell elements in each cell are provided on a common support foil formed to comprise a plurality of juxtaposed pyramids, and a continuous thin film layer is provided on the support foil, and the cells are connected in series.

It is preferred if the cells are positioned in a side by side relationship on a support plate so that neigbouring cells overlap each other so that in the overlapping zones the different electrodes of the concerned cells contact each other directly or through a conductive layer formed preferably by an adhesive.

The assembly of the arrangement gets easier if the cells have slightly oblique directions, and a filling material is positioned between the support plate and the support foils of the cells, and the cells are covered with a transparent support plate through the application of a transparent filling material between the support plate and the upper conductive electrode layer of the cells.

In a preferred embodiment degree of absorption in the visible spectral range of light of all thin film layers is substantially between 85% and 70% which is equivalent with having a reflection substantially between 15% and 30%.

The solution according to the invention provides a significant increase in efficiency by the fragmented utilization of the energy of incident light in solar cells and at the same time it can be manufactured with about the same cost level as conventional thin film cells.

The invention will now be described in connection with exemplary embodiments thereof with reference to the accompanying drawings. In the drawing:

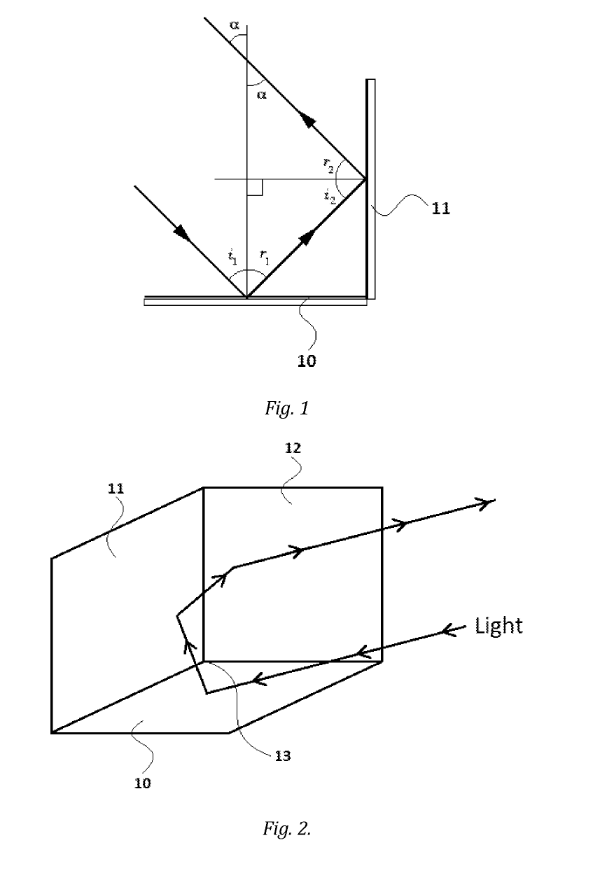

FIG. 1 is a sketch showing the simplest reflection;

FIG. 2 is a sketch illustrating the reflections in a corner cube;

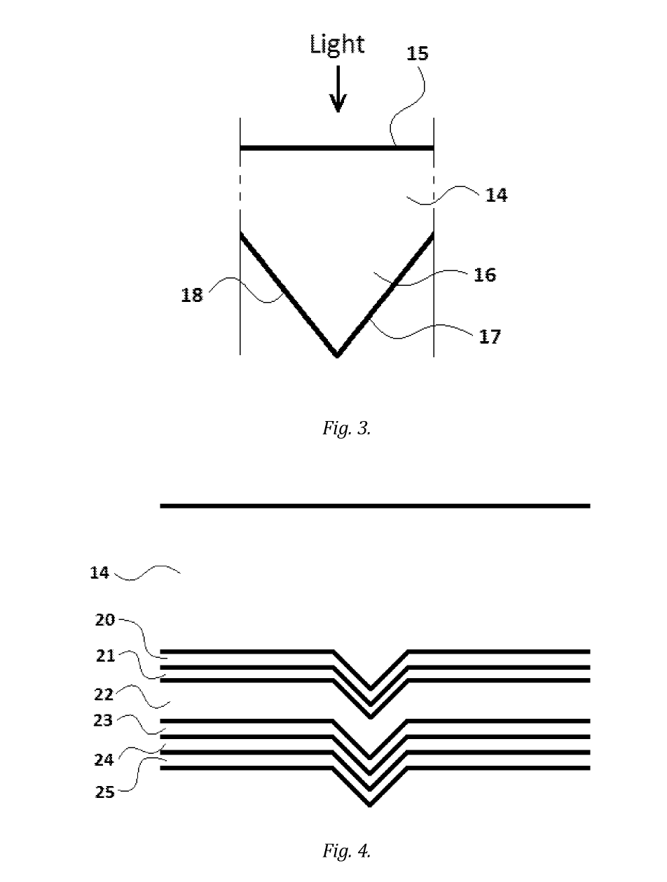

FIG. 3 is the side view of a basic element;

FIG. 4 is an enlarged view with distorted scale to show the arrangement of the layers;

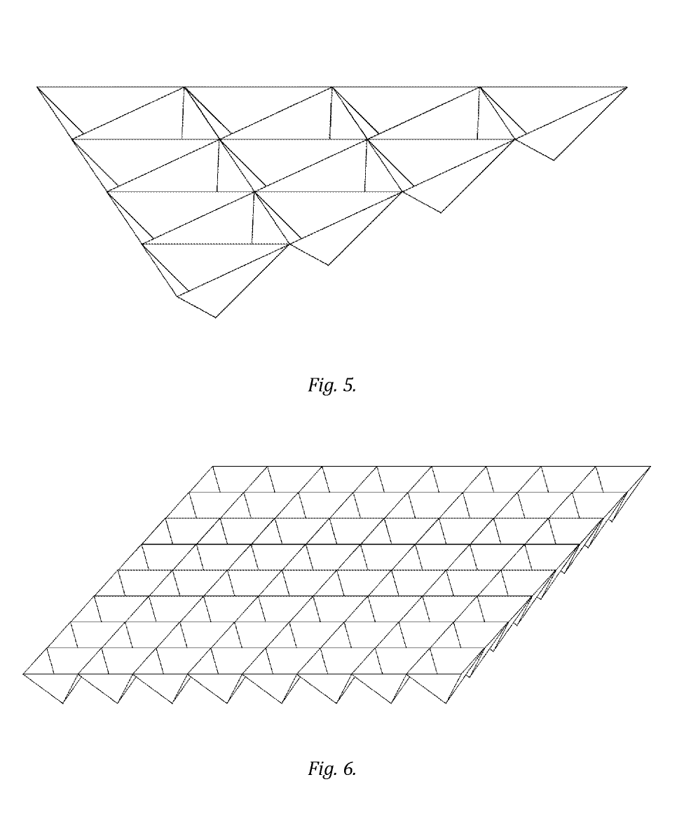

FIG. 5 shows the perspective view of a combined arrangement;

FIG. 6 is the perspective view of a quadratic pyramid arrangement;

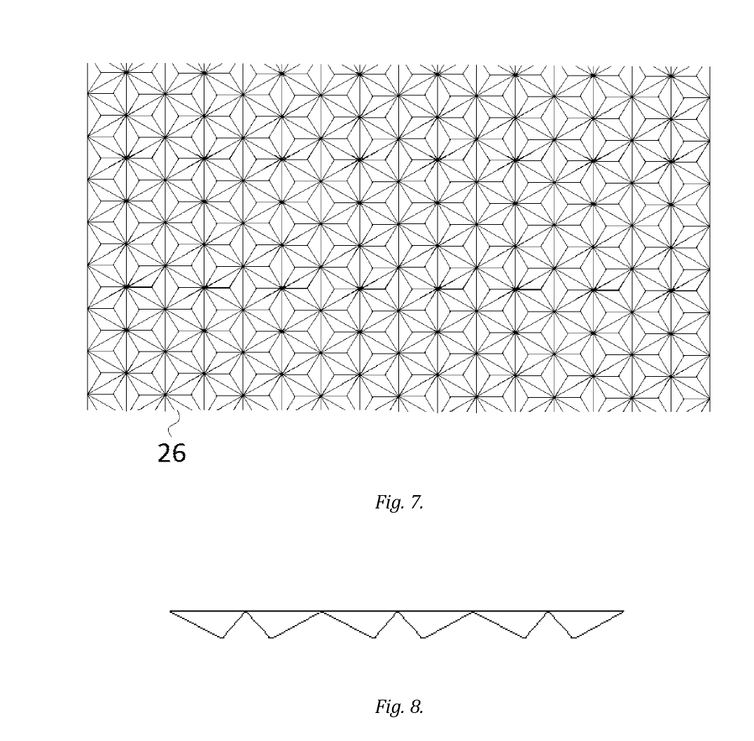

FIG. 7 is the top view of a larger arrangement;

FIG. 8 is the simplified side view of the arrangement of FIG. 7;

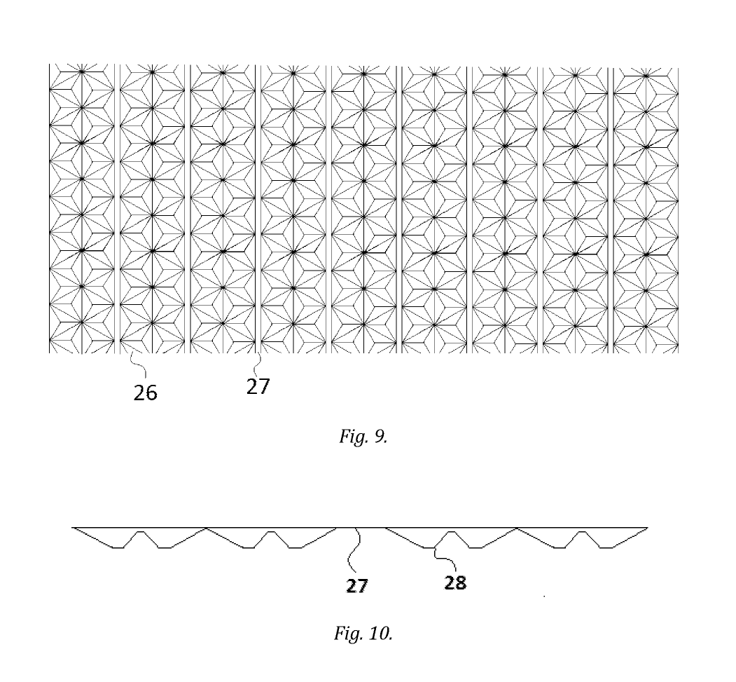

FIG. 9 is a view similar to FIG. 7 but comprises spaces;

FIG. 10 is a side view similar to that shown in FIG. 8;

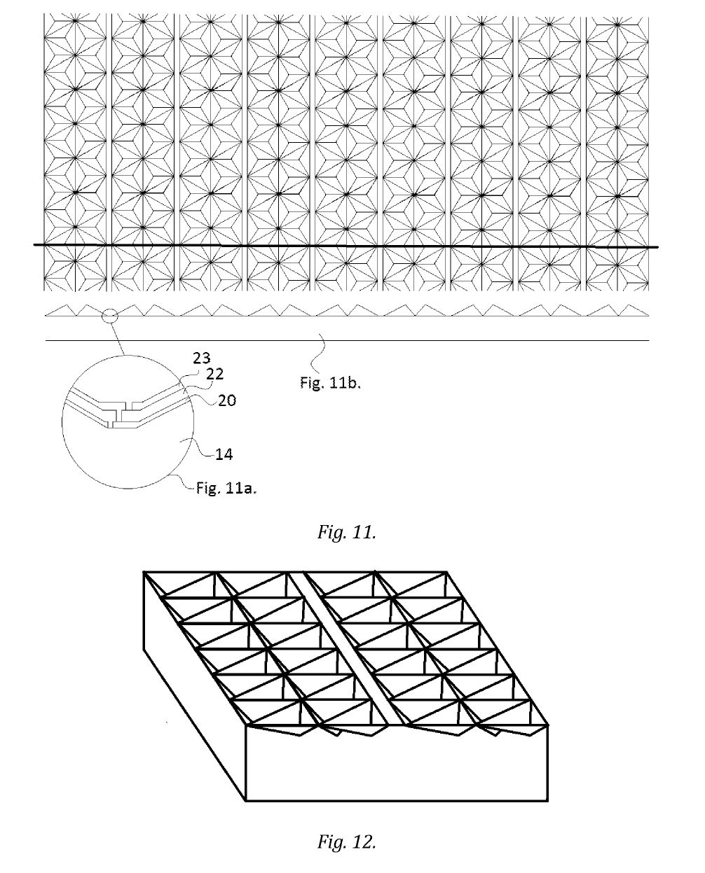

FIG. 11 is a view similar to FIG. 9 in which

FIG. 11a is an enlarged detail;

FIG. 11b is a side view;

FIG. 12 shows the perspective view of the arrangement of FIG. 8;

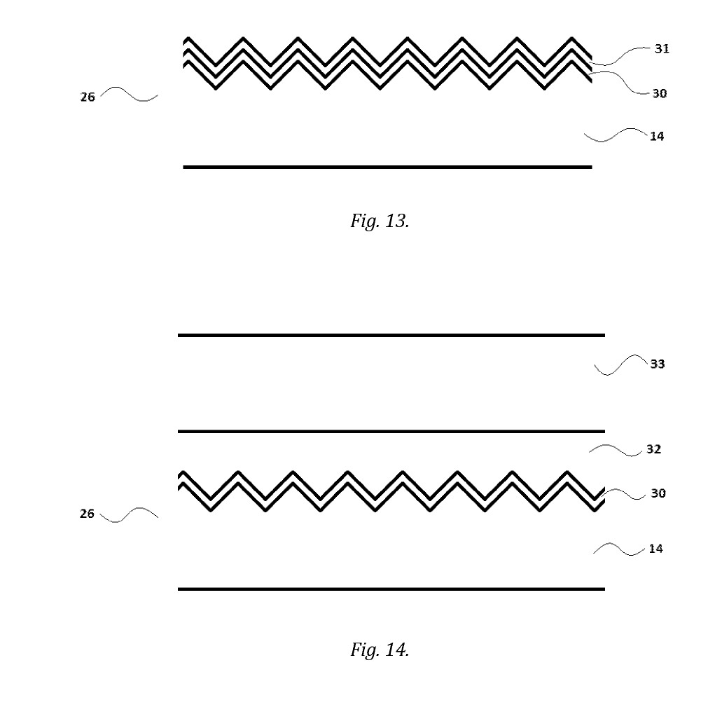

FIG. 13 shows the arrangement of the layers in enlarged scale, and a side view;

FIG. 14 is a sketch similar to FIG. 13 for a further embodiment;

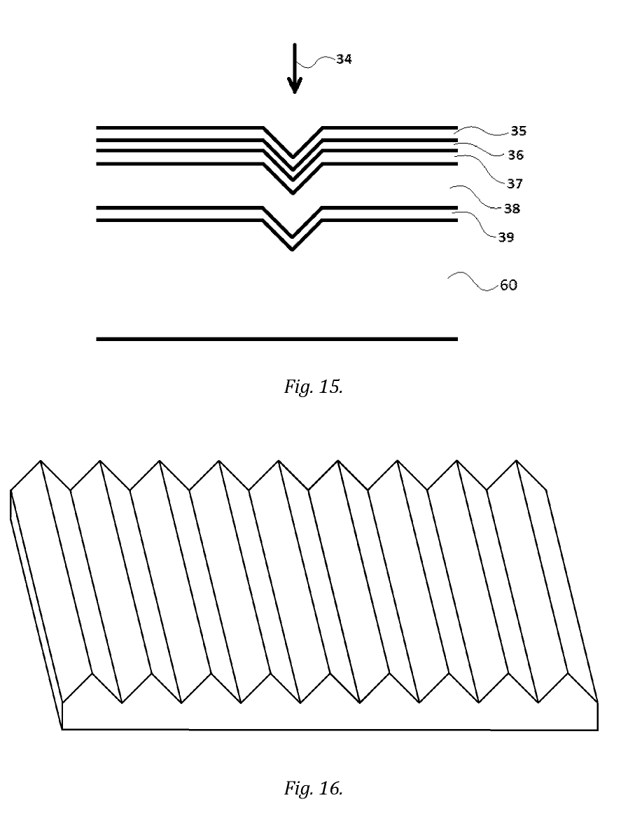

FIG. 15 is a view similar to FIG. 4 relating to an alternative embodiment;

FIG. 16 is the perspective view of a basic element consisting of two parts;

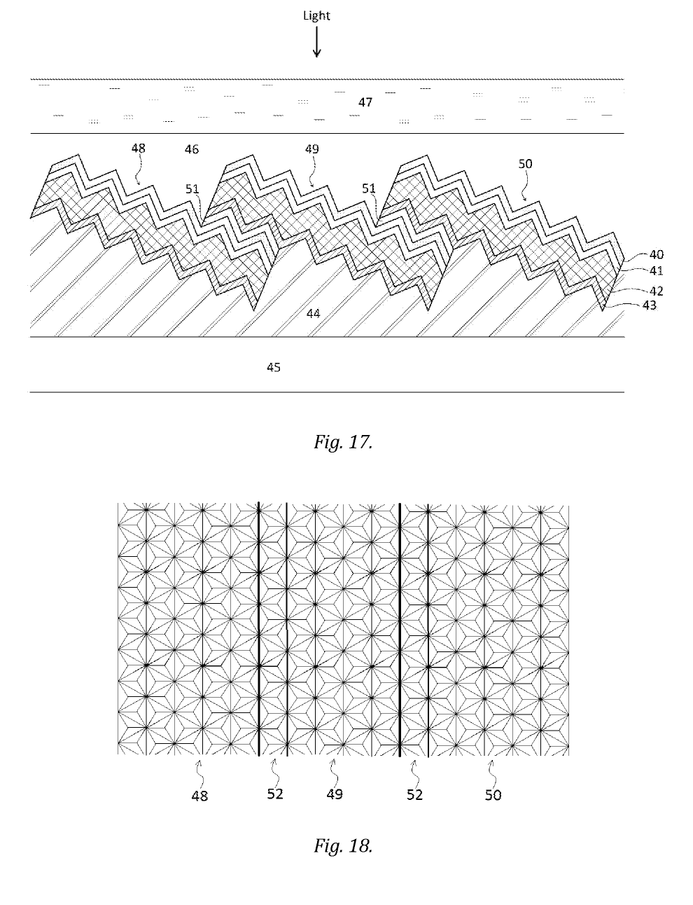

FIG. 17 shows the cross section of a further embodiment with distorted scale; and

FIG. 18 is the top view of the embodiment shown in FIG. 17.

FIG. 1 shows the schematic representation how light is reflected in case of using two mutually normal plates 10, 11 having reflecting surfaces where they receive incident light. Light rays are arriving along a plane that is normal to both of the plates 10, 11 and reach first the plate 10 with an incident angle i₁. They leave the plane 10 in a direction closing an angle r₁ with the incident normal of the first plate 10 and reach the plate 11 with an incident angle i₂ and leave it closing an angle r₂ with the incident normal of the second plate 11. The two incident normals are also normal to each other, and it is clear from the drawing that the reflected light that closes an angle α with the first incident normal will be parallel with the incident light. This statement is true for all angles of the incident light as long as the two plates are normal to each other.

In case the incident light is not normal to the planes of the plates 10, 11, then the reflection properties are illustrated in connection with a corner cube arrangement (FIG. 2) which comprise three mutually normal plates, i.e. in addition to the plates 10, 11, a third plate 12 is used, and all these plates meet at a common point that forms corner 13 of the open cube, and the inner surfaces of the plates are reflecting or mirror surfaces. When showing the path of the light rays the coverage has not been taken into account, but the obliquely incident light will fall first on the plate 10, the light reflected from it falls on the plate 11 and the light from there that has been reflected by the second times will fall from the second plate 11 on the third plate 12. An inherent property of the corner cube arrangement is that the reflected light will be always parallel to the incident light. This property of the corner cube arrangement has long been known and has a wide field of use.

Reference is made now to FIG. 3 showing the cross section of an enlarged detail of carrier 14. The carrier 14 is preferably a glass plate with a planar first surface 15, and at the opposite surface a spatial arrangement is provided e.g. by pressing that comprises upright pyramids composed of three-four or higher number of sides that end at a common apex (peak) as explained in the following part of the specification, and FIG. 3 shows an exemplary pyramid 16. The sides of the pyramid 16 close right angles with each other and form a corner cube which is open from above (if the material of the carrier is disregarded), and in the drawing we can see only the contour lines of two of its plates 17, 18. As it will be explained later, the three plates of the pyramid 16 will constitute a solar cell element after the rear side of the carrier 14 has been provided with appropriate layers. This pyramid shaped solar cell element is considered as the simplest basic part of the present invention, because a plurality of such basic cell elements is formed on the carrier 14. The height of the pyramid 16 lies preferably but not limited to between about 1 and 3 mm and it falls in the range of the thickness of the carrier 14 measured till the basis of the pyramid or the height is somewhat smaller than this thickness so that the carrier 14 can have sufficient mechanical rigidity.

On the rear surface of the carrier 14 which is opposite to the front surface 15 a thin film solar cell structure is provided by means of vapour deposition or by any other way, and the cross sectional structure of an exemplary embodiment thereof that constitutes an amorphous silicon cell element is shown in FIG. 4. The scale of FIG. 4 is greatly distorted in transverse direction and the single pyramid shown in the carrier 14 represent only illustration of a high number of such pyramids as shown in FIG. 3, but the size proportions are also distorted. The enlarged view of FIG. 4 shows the amorphous silicon layers (also in a distorted scale). The first layer made on the surface of the carrier 14 constitutes a light transparent thin electrode 20 which is often referred to as TCO (Transparent Conductive Oxide) layer, made of ZnO and Al material and its thickness is a few hundred nm. Along the light path the next layer 21 is semiconductor p-doped layer that can be very thin, and for an appropriate functioning a thickness of as small as 10 nm can be sufficient. The third (active) layer 22 is in the exemplary embodiment an intrinsic (depleted) layer that has a substantial role from the point of view of the present invention. In customary amorphous silicon thin film solar cells the thickness of the active layer is typically between 200 and 800 nm, and in the present invention this thickness can be smaller or even substantially smaller. The active layer 22 absorbs the most part of light energy falling on the thin film structure. On the other side of the active layer 22 an n-doped layer 23 is provided, and its thickness is somewhat greater than that of the p layer 21, and typically it is between about 50-200 nm. Finally, behind this layer 23 a layer 24 is provided that constitutes the second electrode, and its material is predominantly aluminum and its surface is light reflective, mirror-like, and its thickness is not critical, it is between about 200-400 nm. The rear side of the thin film solar cell with the listed layers must be protected from mechanical effects and this protection is provided by a protective layer 25 that covers the rear side of the electrode layer 24.

The layer structure and actual composition of different thin film solar cells do not form part of the present invention, and the example shown in FIG. 4 serves only the illustration of the structures. Concerning thin film solar cells the pertinent literature provides a very comprehensive description, and one example can be found e.g. in the book entitled “Thin-Film Silicon Solar cells+” published by EPFL Pres on Aug. 19, 2010, editor Arvind Victor Shah, ISBN 9781420066746.

If the rear surface of the basic structure shown in FIG. 3 is provided with the thin film structure shown in FIG. 4, then the incident light will pass through the transparent carrier 14, and through the equally transparent layer 20 and 21 that have bad absorption properties and a part of its energy will be absorbed in the active layer 22 and generates there charge carrier pairs. These charged particles will proceed in the direction of the appropriate layers and electrodes. The electrical resistance of the active layer 22 is comparatively high, and during the travel path a portion of the previously separated particles will get recombined that constitute a recombination loss. Typical thin film solar cells are designed in such a way to absorb all or most of the incident light energy. One of the basic findings of the present invention lies in that there is no need to increase absorption above a limit value and totally reduce reflection but instead of it a reduced thickness of the active layer 22 can be used, whereby the aforementioned resistive and recombination losses will also decrease, but the degree of light absorption will also decrease because a thinner layer can absorb a smaller amount of incoming light energy. The light not absorbed during the passage through the active layer 22 will proceed and reach the reflecting surface of the second electrode layer 24, its direction will get reversed and this reflected light will pass again through the active layer 22. A further part of its energy will be utilized there again to generate charge carrier pairs, and the reflected remaining light will leave the surface 15 of the carrier 14 and proceed further to reach a further planar surface of the pyramid as shown in FIGS. 1 and 2 which is provided with the same thin film layers and from electrical point of view constitute a further segment of the basic cell element. A part of this light will be utilized at this second cell fraction. A small portion of the light which has not been absorbed will be reflected from this second cell fraction towards the third planar surface where its energy will be utilized again.

In the described way and by means of actively using the reflections between the planes of the pyramid a substantial portion of the energy of the incident light will get utilized (although not by the passage through a single layer but through two or more of such layers). In this way a full or nearly full absorption can be reached, but the decreased thickness of the active layers 22 compared to conventional thicker layers that provide a higher degree of absorption will decrease both the resistive and recombination losses, whereby the efficiency increases. In addition to these effects a further advantage will be apparent, namely the spectral properties of the passage of light through several spaced thin films is favourable. It can be proven that in case of absorption through several separate layers in the respective absorption stages the wavelengths corresponding to maximum absorption will get shifted, therefore when absorption is provided in separate stages the absorption will more efficiently utilize the full spectral range of the energy of the light as if the same absorption would have taken place in a single layer.

The extent of the reduction of the thickness of the active layer 22 depends largely on actual design and structure of any given embodiment, therefore the exact values and optimum should be calculated on a case by case basis. A definite improvement can already be experienced when the absorption during passage of the first thin film is less than 90% in the visible range of light i.e. more than 10% energy is reflected towards the second spaced planar part of the same cell element. The optimum range depends on several components, and can be between about 15 to 30% reflections, but a value of 50-60% reflection from the first planar thin film can provide improved efficiency. There is no sharp lower limit of the absorption of a thin film layer, but in case of too small absorption (and high reflection) values there will be a remarkable loss of the light energy that leaves the third or last thin film layer.

A further advantage of the suggested design comes from the previously mentioned properties of corner cubes, i.e. the basic cell element can function within a wide range of incident angles relative to the direction of the diagonal of the cube, namely if the diagonal is adjusted in the direction of the maximum of the incident light at the given geographic site, then even without moving the cells energy can be generated each day through a great part of available daytime.

In FIGS. 5 and 6 the structure has been shown without the carrier glass plate i.e. the side-by-side relationship of the basic cell elements. In FIG. 5 the previously described corner cube, i.e. a three-sided pyramid constitutes all basic cell elements, but with differing optical properties favourable results can be obtained by using four-sided, quadratic-based pyramids as shown in FIG. 6, and the basic cell element can also be realized by regular hexagonal or octagonal pyramids. The actual optimum design should be determined based on individual conditions.

FIG. 7 shows the top view of a solar cell board 26 using the corner cube arrangement as shown in FIG. 5, in which the respective basic cell elements (corner cubes) are arranged in rows and columns and fill the available surface. FIG. 8 shows a transverse view of the structure of FIG. 7, in which only a planar connecting line of the glass carrier has been shown that interconnects the mouth openings of the pyramids and the side lines of the downwardly extending pyramids are also shown. In the design as shown in FIG. 8 the pyramids have sharp tips (peaks), and the basic cell elements are arranged closely sideby-side. Such a theoretically most dense design is not optimum from at least two grounds. Solar cell blocks are generally not designed to the voltage provided by a single cell, but the series connection of several cells is preferred. In case of the dense design shown in FIG. 7 the series connection of the cells is difficult to be realized. The other aspect comes from the limitations of the vacuum deposition method by which the cells are made, because the layers cannot be well deposited at sharp edges and peaks, and at such locations scratches can be formed in the layers.

FIGS. 9 and 10 are views similar top and transverse views to FIGS. 7 and 8 for a board that has several solar cell units. Between the basic cell elements arranged in rows and columns after a predetermined number of columns spaces 27 are provided and these spaces will be taken into account when the carrier 14 is pressed. In addition to the formation of the spaces 27 a further difference compared to the previous embodiment lies in that the peaks 28 of the pyramids are blunt and have no sharp tips in order to facilitate the formation of the layers and make them more durable.

In FIG. 11 and in its detail views of FIGS. 11a and 11b the same structure has been shown but in case of the side view of FIG. 11b the view has been illustrated when seen from the other direction. In the enlarged detail of FIG. 11a the respective layers were associated with the same reference numerals as in case of FIG. 4. It can be seen that when the layers are formed, at different locations and in different depths the layers are cut in parallel with the main direction of the spaces 27, and on the positions of these cuts during the formation of the layers respective conductive layers will be deposited which automatically establish a series connection between the parallel cell units between each pairs of neighboring spaces 27. FIG. 12 shows the perspective view of such a solar cell board.

FIG. 13 shows a detail of the side view of a solar cell board 26 in an enlarged schematic illustration and this shows that the solar cell structure 30 detailed in FIG. 4 and provided on the carrier 14 is protected from outer mechanical effect by a comparatively thick protective layer 31, that can be made from a gel-like self hardening material or it can be any shock-resistant material that also resists outer thermal and other effects.

FIG. 14 shows a structure with higher degree of protection, that differs from the one shown in FIG. 13 in the presence of a protective glass board 33 attached in a spaced way to the carrier 14 by binding elements or by a frame not shown in the drawing, and the space 32 between the two boards is filled by a filler material e.g. a gel, a foam or a similarly soft material that protects the solar cell structure 30.

In the foregoing part of the specification the thin film solar structure has been shown as having amorphous silicon design, in which pyramids forming the basic cell structure were projecting outwardly from the rear side of the glass carrier.

The solution according to the invention functions just as well in a structure which is inversely directed compared to the previously described arrangement, in which the pyramids do not extend out from the rear side of the glass plate but they form pyramid recesses. In this case the layer structure of the cell should be inverted, since the mirror surface should be the farthest layer along the path of the incident light. FIG. 15 shows a sketch of such an inverse structure that corresponds to FIG. 4. The direction of the incident light is shown by arrow 34, and along this direction there is a transparent protective coating 35, an electrode surface 36 that can be the previously described TCO layer, a semiconductor layer 37 e.g. a CdS layer, and an active layer 38 that can be made of a CIGS layer. The CIGS layer is a semiconductor layer which is Cu(In,Ga)Se2 (copperindium-gallium-di-selenide), and this is the short name of thin film solar cells based on this compound. In this solar cell the CIGS layer corresponds to a p type layer. In this solar cell the CdS layer is the n-type layer and the name refers to a cadmium-sulfide material. The ZnO is a kind of TCO layer and it is a zinc-oxide. The most remote layer is the mirror layer 39 formed e.g. by molybdenum. This solar cell structure is built on carrier 60.

In such CIGS solar cells that have e.g. respective glass carriers the recesses that correspond to the pyramids of the basic structure are at the side of the carrier in which the light rays enter, and the carrier can be made e.g. by pressing. In all other aspects the design of the basic structure, the fixing of the layers and the design of the spaces can be provided on the basis of identical principles with those used at the previously described embodiments.

The solution according to the invention is preferred not only in case when the light falling on a cell of the basic structure proceeds to two or more further cells, because the substantial advantages are experienced already in case of two cells. Such an arrangement is shown in FIG. 16 in which the basic structure is constituted pairs of solar cells elements that close an angle with each other but their planes are parallel, and the cell elements meet along a common edge, and the recess receiving the incident light is above this edge. In FIG. 16 the whole structure forms a single cells, however, the series connection can be realized e.g. in the same way as described earlier by using spaces.

Reference is made now to FIGS. 17 and 18, in which a further embodiment of the solar cell arrangement according to the invention is shown. FIG. 17 is illustrated in a distorted enlarged scale so as to illustrate the arrangement of the different parts of the thin film structure visible. The example shows three solar cells 48, 49 and 50 of substantially identical design, which are made first as independent units and are placed during the manufacturing process in a separate step on a support plate 45 covered by a filling material 44 that can adapt and receive the special spatial shape of the cells 48, 49 and 50 when placed thereon.

The cells are made on a metal support foil 43 that has a light reflecting upper surface, and has a certain degree of rigidity. It can be a stainless steel foil of about 0.1 mm thickness and has a width that corresponds to the width of the solar cell e.g. as shown in the top view of FIG. 18. The originally planar support foil which is available in rolls is first pressed to have a spatial design that consists of a high number of regularly arranged corner cubes having about the same shape what is shown in FIGS. 5 and 7. Following the formation of the corner cubes the foil is cut into parts of predetermined lengths, and the thin film layers are provided then on the reflecting surface of the so formed support foils 43 e.g. by vacuum deposition. The support foil 43 constitutes the second electrode of the thin film cells provided thereon. The layers formed in this step can be the same or similar to those described previously, in this embodiment layer 42 is the second active layer (when seen from the direction of incident light, and this is preferably a cadmium telluride CdTe or CIGS layer being copper-indium-gallium-selenide. The next layer 41 is the first active layer which is preferably a CdS i.e. cadmium-sulfide layer, and layer 40 thereon is the first electrode layer which is preferably a TCO layer as described earlier. The thickness of each layers correspond substantially to those described at the previous embodiments, and can be parameters of actual design.

Following the deposition of the aforementioned layer the metal foil 43 which takes the role of a provisional carrier as it has sufficient rigidity for playing this role, is then placed on the surface of the support plate 45 covered by the deformable filling material 44 in a slightly oblique way as shown in FIG. 17 to form the cell 48. The next similar cell 49 is placed with a predetermined overlap 52 on the top of the lower end region of the previous cell 48 so that an electrically conductive layer 51 is provided on the top of the cell 48 in the overlapping region. In this way the upper first electrode layer 40 of the cell 48 will be electrically connected to the second electrode layer of the next cell 49 formed by its foil 43. The last cell 50 will be positioned in a similar way on the other end region of the cell 49 also with the same overlap 52, whereby the cells 48, 49 and 50 will be connected in series, wherein the first connection terminal of the solar cell arrangement will be connected to the foil 43 of the first cell 48 and the second connection terminal will be coupled to the first electrode layer 40 of the last cell 50.

For making a mechanically stable solar cell arrangement or panel, the top of the cells, i.e. on the electrode layers 40 a light transparent soft filling material is placed which holds a light transport e.g. glass cover plate 47 which extends substantially parallel with the support plate 45.

The number and the width of the cells used in an actual solar panel can be designed according to actual needs of the end users, and they have preferably one of the standard sizes.

The present invention can be realized in a number of ways different from those described in the foregoing embodiments, and the size of a cell element need not be as small as described, in certain fields of applications a cell element can be quite large, but for applications in more or less standard solar panels the suggested size parameters can be preferred.

The solar cell element and the solar cell arrangement described have the advantages described, which include the increased efficiency without the increase of manufacturing costs, the better utilization of the full spectral range of incident light and the decreased need to turn the planar surface to follow the movement of the sun, or in fixed installation the longer active period each day provided by the described properties of corner cubes. The solution according to the invention therefore makes possible for those skilled in the art to make several not disclosed embodiments by using the described principles therefore the scope of protection cannot be limited to any one of the examples shown.

1-15. (canceled)

16. A solar cell module composed of a plurality of solar cell elements positioned side-by-side relative to each other, wherein each solar element comprises a portion of a carrier (14) which is common for all of said solar elements; a thin film layer structure provided on a surface of the carrier covering said solar cell elements and being mechanically supported by the carrier, and when said cell is seen from the direction of incident light the thin film layer structure comprises a transparent and electrically conductive first electrode layer (20); active layers (22, 23) in which a portion of the energy of the incident light is absorbed and an electrically conductive second electrode layer (24), wherein light energy absorbed in the active layers (22,23) generates positive and negative charge carriers that proceed to a corresponding one of said first and second electrode layers (20, 24), said thin film layer structure has a light reflecting rear boundary surface and the surface of said carrier (14) on which said thin film layer structure is provided comprises for each of said cell elements at least two substantially planar surface regions that close an angle with and form continuation of each other so that between them a recess is formed, and a portion of light reflected from said rear boundary surface of a first one of said planar surface regions in each cell element will pass through said recess to fall on the second one of said planar surface region of the same solar element, and said thin film structure is uniform and uninterrupted for the cell elements constituting said solar cell, characterized in that said active layers (22, 23) have a decreased thickness and overall absorption, whereby a portion of the incident light reaches said light reflecting rear boundary surface behind the active layers (22, 23) being reflected and returned towards the transparent first electrode layer (20) and generate again charge carriers in the active layers (22, 23) then pass through said recess to reach and penetrate in the active layers of the other one of said planar surface region of the same cell element and generates there further charge carriers, wherein the total absorption of light measured between the amount of said incident light in the visible spectral range that has entered said first electrode layer (20) till the reflected light leaves said first electrode layer (20) is less than 90% i.e. more than 10% of the incident light entering the active layers (22, 23) of a planar surface region will leave the same planar surface region to proceed to the next one of the planar surface regions.

17. The solar cell module as claimed in claim 16, characterized in that the degree of absorption in the visible spectral range of light of said thin film layers is substantially between 85% and 70% which is equivalent with having a reflection of the absorbed light substantially between 15% and 30%.

18. The solar cell module as claimed in claim 16, characterized by comprising at each of said cell elements respective three of said planar surface regions that form a pyramid, and light reflected from any of said regions will reach a neighbouring further region.

19. The solar cell module as claimed in claim 18, characterized in that the planar surface regions are arranged to form a corner cube in which the tip falls in the deepest part of the recess.

20. The solar cell module as claimed in claim 16, characterized in that said reflecting surface is formed by a light reflective design of said second electrode (24).

21. The solar cell module as claimed in claim 16, characterized in that the extent of said total absorption is decreased by decreasing the depth of at least one of the active layers (22, 23).

22. The solar cell module as claimed in claim 18, characterized in that said carrier (14) is a rigid substantially planar plate and said pyramids being juxtaposed to substantially fill the surface of the carrier (14).

23. The solar cell module as claimed in claim 16, characterized in that that the surface of the carrier (14) that faces towards incident light is a planar surface, and the spatial arrangement of the cell elements comprising projections and recesses is formed at the rear side of the carrier (14).

24. The solar cell module as claimed in claim 16, characterized in that the rear surface of the carrier (14) is a planar surface and the spatial arrangement that comprises projections and recesses is formed at the front side of the carrier.

25. An arrangement of a plurality of solar cell modules as claimed claim 16, characterized in that said solar cell modules are built in a side-by-side arrangement and mechanically fixed on a common support plate (14 or 45) and each solar module has a pair of electrical terminals, wherein at least a portion of said solar cell modules are electrically connected in series with each other.

26. The solar cell arrangement as claimed in claim 25, characterized in that said common support plate is constituted by a carrier (14) common for all modules, and each of said solar cell modules have respective linear boundaries and substantially rectangular shapes, and the solar cell modules are arranged in rows and columns, and certain neighbouring rows or columns are spaced along their adjacent sides whereby respective spaces (27) are formed, and respective grooves are provided along the spaces that extend across said film layers between the first and second electrode layers (20, 24) wherein an electrically conductive material is placed in the grooves that connect one of the two electrode layers (20, 24) of a first module with the other electrode layer (24, 20) of the adjacent module, whereby these modules are connected in series with each other.

27. The solar cell arrangement as claimed in claim 25, characterized in that each of said modules are constituted by respective separate cells (48, 49, 50) that have separate carriers formed as separate electrically conductive support foils (43) shaped to constitute a plurality of juxtaposed spatial pyramids of the cell elements therein, and the support foils (43) are arranged at the side of the associated modules which is opposite to the side facing the incident light, and the support plate (45) common for and holding all modules is connected to the rear sides of the support foils (43), and said cells (48, 49, 50) are connected in series.

28. The solar cell arrangement as claimed in claim 27, characterized in that said cells (48, 49, 50) are positioned in a side by side relationship on the support plate (45) so that a respective side regions of neighbouring cells (48, 49, 50) are placed on one another to overlap each other and in the overlapping zones the different electrodes of the concerned neighbouring cells (48, 49, 50) cells contact each other.

29. The solar cell arrangement as claimed in claim 28, characterized in that the cells (48, 49, 50) have slightly oblique directions for facilitating placement of the overlapping zone on one another, and a filling material (44) is positioned between the support plate (45) and the support foils (43) of the cells (48, 49, 50).

30. The solar cell arrangement as claimed in claim 29, characterized in that for the protection of the arrangement a transparent font support plate (47) is positioned in front of the light receiving sides of the cells (48, 49, 50) and a transparent filling material (46) is placed between the upper sides of the cells (48, 49, 50) and the rear side of the front support plate (47) to fill any gap therebetween.
